(19) United States
(12) Patent Application Publication
(10) Pub. No.: US 2004/0175938 A1
(43) Pub. Date: Sep. 9, 2004

(54) Method for metalizing wafers

(76) Inventor: John Grunwald, Ramat-Gan (IL)

Correspondence Address: John L. Cordani, Carmody & Torrance LLP, 50 Leavenworth Street, P.O. Box 1110, Waterbury, CT, 06721-1110, US

(21) Appl. No.: 10/803,765

(22) Filed: Mar. 18, 2004

Related U.S. Application Data
(63) Continuation-in-part of application No. 10/307,510, filed on Dec. 2, 2002, now abandoned.

(30) Foreign Application Priority Data
Jun. 23, 2002 (IL) 150364
Jul. 3, 2002 (IL) 150577
Jul. 24, 2002 (IL) 150940

(51) Int. Cl. H01L 21/44

(52) U.S. Cl. 438/678

(57) ABSTRACT

A method of depositing metal on the surface of a silicon wafer. The method comprises (i) contacting the silicon wafer with a solution comprising non-precious metal ions, and (ii) thereafter contacting the silicon wafer with a solution comprising a reducing agent. The silicon wafer is preferably contacted with the foregoing solution by creating a puddle of the solution on the surface of the wafer.

### FIELD OF THE INVENTION

This is a continuation-in-part application of currently co-pending application Ser. No. 10/307,510, filed Dec. 2, 2002.

### BACKGROUND OF THE INVENTION

U.S. Pat. No. 4,199,623 to Nuzzi et al, U.S. Pat. No. 3,993,491 to Feldstein and U.S. Pat. No. 4,082,557 to Pizzo are referenced herewith, in addition to prior art patents referenced in the co-pending application Ser. No. 10/307,510, published as US-2003-0233960, the contents of which are incorporated herein by reference. Briefly summarizing above referenced patents, they teach the use of silver as a catalyst for electroless deposition (Pizzio), or compositions comprising both copper and stannous ions that are then reduced on the surface of the polymer to act as electroless copper catalysts (Feldstein), or a given ratio of complexes of cuprous and cupric ions (Nuzzi), said cupric/cuprous ions are then reduced on the polymer surface to form an electroless catalyst. Above referenced patents have not achieved reduction to industrial practice, and in a way teach away from this instant patent.

It is noted that the prior art of electroless plating over polymer surfaces, predominantly relies on immersion techniques. In immersion plating, the workpiece to be plated is dipped sequentially in a series of processing solutions separated by water rinses, to minimize contamination by “drag-in”, a term used to denote undesired carrying by the workpiece of a given processing bath or solution to the next.

Some of the shortcomings of prior art immersion-based electroless plating techniques are:

1. Excessive and costly consumption of rinse water, a burden on the environment.

this patent minimizes rinsing needs/problems.

2. Use of costly and cumbersome automated equipment designed to immersing the workpiece in the many processing solutions and rinsing stations that separate them. This invention can use equipment already available in wafer fab lines.

3. Immersion techniques necessitate relatively large volumes of processing solutions, a special disadvantage with semi—or unstable electroless plating compositions, i.e. formaldehyde-based electroless copper.

### SUMMARY OF THE INVENTION

Above pending application No. US-2003-0233960 discloses methods and compositions that electrolessly deposit metals, i.e. copper, on non-metals, especially polymer-based Printed Circuit Boards (PCBs). The methods of above application comprise immersing the non-metallic substrate in an aqueous solution of reducible metal ions, followed by immersion in a reducing solution, preferably DMAB solutions comprising ppm levels of copper or silver ions that are shown to “energize” the reducing action of DMAB. Above pending application postulates that said reducing solution is “energized” or enhanced by way of hydrogen that is generated in said DMAB solution, formation of metal hydrides on the surface to be metalized, or a combination of both. The reduced metal, or the metal hydride thus formed on the non-metallic surface, then serves as activator or seeder for electroless deposition of copper.

The present application focuses uniquely on metallization or electroless plating of Si-based wafer substrates, more specifically semiconducting Si/SiO₂ wafer substrates, used in the fabrication of ULSI devices. Indeed, wafer substrates afford numerous, novel processing possibilities. Wafers are unique, among other reasons, by virtue of their temperature resistance, which enables the use of elevated processing surface temperatures that are inapplicable with polymer substrates. Indeed, polymers are known to be prone to heat degradation. The surface of the wafer can thus be heated to a predetermined, optimal temperature, well in excess of 100 deg. C. (the approximate b.p. of aqueous compositions), prior to being contacted with a solution, or during its contact with the solution. Also, the wafer surface can be cleaned via plasma or other gaseous techniques, often a preferred option for cleaning wafers prior to processing, especially prior to metalization.

It is a central consideration of the present invention to provide methods and compositions that are uniquely and specifically suited for wafer metalization from aqueous media, as distinct from aqueous metallization of polymers via immersion.

It is an object of this patent to provide an improved method for metallizing or electrolessly plating semiconductor substrates without precious metal seeding, or activation, by depositing thereon a non-precious metal or a non-precious metal derivative such as metal hydride, which then acts as seed or catalyst in subsequent electroless deposition.

It is another object of this invention to provide a method to aqueously metalize silicon wafers, the method comprising rotation or spinning of the wafer during at least one step of the metalization process, or preferably at times, throughout the entire metalization cycle. Above improved metalization method is not unlike techniques used in ULSI imaging of photoresists.

A further object of this patent is to minimize or eliminate immersion steps handling of wafers to be metalized, by preferably dispensing onto the wafer substrate at any stage of the metalization sequence, a solution, or water, as required by the metalization process, thereby replacing immersion step or steps. A still further object of this invention is to repair metal defects in ULSI devices, especially as they relate to copper dishing.

A yet additional object of this invention is to allow “direct writing” of metal patterns, i.e. conductors, on a wafer substrate without first patterning an image via photoresist.

Another preferred object of this invention envisions electroplating copper (without first electrolessy plating a metal, for example copper) on the wafer substrate, following deposition of a layer or fraction of layer comprising non-precious metal or non precious metal derivative i.e. metal hydride.

Thus, the present invention provides a method of electrolessly depositing a metal on at least a part of the surface of a silicon wafer substrate, comprising:

(a) contacting the silicon wafer substrate with a solution comprising non-precious metal ions so as to obtain a wafer substrate covered with non-precious metal ions; and

(b) exposing the wafer substrate obtained in step (a) to a reducing solution comprising a reducing agent for reducing the metal ions that cover said substrate to a lower oxidation state.

The method of the present invention visualizes dispensing small/minimal amounts of liquid solution onto the wafer substrate. After the desired interaction/reaction at the wafer/puddle interface is completed, the liquid contained in the puddle is spun off by rotating the wafer at a given speed, leaving the wafer surface essentially dry, and devoid of residual liquid on the surface. The wafer substrate is then ready to receive the solution dictated by the next process step.

In addition to minimizing water consumption, above embodiment of the invention potentially reinforces the metalizing reaction by leaving the wafer substrate with a greater concentration of reacting compound, than would be the case if immersion rinsing took place. An indication of such preferred reaction can be found in the co-pending application, by comparing example 1 vs. example 2.

It is noted that electroless copper plating can be embodied via compositions enumerated in co-pending U.S. patent application Ser. No. 10/307,510, or using a host of other compositions of the prior art, the majority of which rely on formaldehyde as the main reducing agent. This instant application proposes using preferably, but not limitingly, hypophosphite-based electroless compositions as the principal reducing agent for depositing either elecroless copper, electroless nickel, or alloys thereof. The use of hypophosphite as possibly the reducer of choice (as opposed to formaldehyde), is of special importance in embodiments of this instant application calling for heating the wafer substrates, or supplying radiant energy to the wafer substrate, before, during, or after its contact with the electroless solution. Indeed, formaldehyde compositions are environmentally objectionable, having been suspected in the literature as potentially carcinogenic.

Among the benefits of the present invention is that it provides a process where the immersion in at least part of the process steps, is replaced by contacting the wafer with a “puddle” of the desired solution or rinse. By puddle, it is meant that a given solution is dispensed on the wafer surface forming a pool (or puddle), not unlike techniques practiced in photoresist imaging. The wafer surface itself, thus acts as the “container” or “vessel”, where a given surface reaction can take place.

The liquid dispensed on top of the wafer substrate by “framing” or surrounding the wafer periphery with a circular dam or “wall”, allows the use of increased volumes of solution, volumes that are not afforded by the pool or puddle as described previously. It is to be understood that the term puddle in this invention, includes the embodiment of above proposed “raised wafer periphery” as well, affording larger pool volume when needed.

### DETAILED DESCRIPTION OF THE INVENTION

This instant invention exploits the very unique features that are inherent in silicon-based wafer surfaces, mainly “spinnability” and heat resistance.

Again as mentioned before, a preferred embodiment of the invention contemplates dispensing onto the surface of the wafer (as it is preferably, though not limiting, mounted on a spinner head) a desired amount of a given solution required by the metalizing process, allowing it to form a meniscus, pool, or puddle, which is a substitute for immersing the wafer in said solution.

The term Puddle, Puddle Processing (PP) as used in this invention, denotes placing a desired amount of liquid solution on the surface of the wafer substrate, where it forms a pool or puddle, allowing the puddle to stay in contact with the wafer substrate for period of time sufficient to achieve a given result or reaction. The puddle can be delivered onto the wafer substrate by means of automated spay nozzles, or somewhat crudely, by manually using a pipette filled with said liquid solution, or by any other means.

Also, the wafer can be stationary during or after delivery of the puddle, it can slowly/moderately rotate or spin during and/or after delivery to promote spreading of the liquid solution to the periphery of the wafer, or both. The operator can alternately use rotational or stationary wafer processing, repeating it intermittently, if needed to deliver fresh processing liquid.

The height of puddle or pool can be adjusted/controlled via the surface tension of the liquid solution to be dispensed on the wafer substrate, by the previously described construction of a “dam” around the periphery of the wafer, or both.

U.S. Pat. No. 6,372,408 to Lawson is a potentially helpful example of similar techniques applied to photoresist development.

Again, the term “Puddle Processing” (PP) as used in this invention, denotes dispensing a predetermined quantity of a given liquid onto the center of a stationary, or a minimally rotating wafer substrate that promotes spreading of the liquid across the wafer surface, allowing it to be in contact with the wafer surface for a desired period of reaction time to complete the wafer/solution interaction, then spinning or rotating the wafer at a given speed, causing centrifugal forces to remove the liquid off the wafer periphery.

The liquid dispensed onto the center of a wafer can be water (for example for rinsing), an organic solvent to facilitate drying, or a chemical composition desired to achieve a given surface reaction.

Also, in order to speed up and facilitate a given surface reaction with the liquid, the wafer surface can be heated to a given desired surface temperature prior to dispensing a given liquid onto it, or following the dispensing of above liquid, or both. Indeed, the flatness of the wafer surface conveniently enables supplying radiation energy, such as for example, laser energy to the solution/wafer interface. In choosing the optimal type of energy, one can form draw drawing on the wealth of prior methods used in radiation chemistry for polymers, photopolymers, solid state, etc.

Again, after allowing the liquid to stay in contact with the wafer surface for a desired time period, and at a given temperature needed to achieve the desired result, increasing the rotational speed of the surface spins off the liquid.

Further, while a preferred embodiment of the patent envisions the use of puddle or PP in all steps leading to metalization, it also contemplates the use of a combination of immersion and PP where it offers process advantages.

Also, in cases where a given amount of liquid dispensed on the wafer surface is insufficient to achieve a desired result, the invention can be embodied by spinning off the “exhausted”, and applying a fresh quantity thereof, with or without rinsing in-between, referring to such method as multiple puddle. Multiple puddle may be especially advantageous in the case of electroless solutions applied to the wafer surface, as it insures supply of fresh/ uncontaminated and unexhausted solution.

The invention contemplates applying energy to the surface of the wafer during or after a given process step to enhance a given reaction, or for the purpose of annealing a metal deposit to reduce stresses during or after electroless or electroplating of copper, etc.

A preferred embodiment made possible by this invention is the option to repair defects of interconnects metals such as copper. It envisions dispensing an as-needed, possibly small amount of metalizing solution, i.e. electroless copper, to a pinpointed defective area, in order to deposit the needed additional thickness of metal. Deposition or metalization can be synergistically enhanced by delivering radiant energy to the “pinpointed” defective spot to be “repaired” by electroless metalization. Radiation energy can be delivered before, during, or after metalization of said area. This embodiment can serve as a very convenient tool for repairing dishing defects before, during or following CMP operations.

As mentioned previously, the patent enables the generation of metal patterns directly on the wafer surface, without first resorting to photoresist imaging. This can be accomplished by digitally and selectively scanning the seeded or activated wafer surface with an appropriate laser, wherein the laser forms an image or pattern, as it deactivates or activates the seeded wafer surface. The thus formed image, is then reinforced by electroless plating. For example, it is postulated that metal hydride covering the wafer surface will be decomposed or “decatalyzed” when interacting with a computer commanded laser. Such areas will not trigger or catalyze electroless deposition. It is thus contemplated that areas that have been scanned with laser will not plate in electroless bath because the activator on the wafer substrate ( i.e. metal hydride) has been ‘deactivated’, whereas areas not exposed to the laser will indeed plate, thereby selectively forming a metalized pattern. In selectively patterning an electroless image on a wafer substrate, one can be aided by the prior art of digital printing, and/or direct write photoresist imaging as practiced in the area of printed circuits (PCBs).

In practicing this invention, one can be guided by teachings and Examples disclosed in co-pending application Ser. No. 10/307,510, and incorporated herewith by reference. Persons skilled in the art will of course find other means accomplish desired objectives of the invention in fabricating ULSI devices.

At the risk of being redundant, it is stated again, that the very detailed disclosure of the chemistry and mechanisms described in the sections of “Summary of the Invention” and “Detailed Description of the Invention” of pending application Ser. No. 10/307,510, will be conveniently relied-upon in achieving many, if not all the objectives of this instant invention . It is of course anticipated that one skilled in the art will make the necessary adjustments and refinements, as dictated by the various objects to be achieved in metalizing wafers for use in ULSI devices.

The following steps will generally be followed in pursuing the various objects of the invention:

1. The wafer substrate will be “equipped” with, supplied with, metal nuclei, or nuclei of metal derivatives, such as metal hydrides. Metal hydrides, for example, can be obtained on the wafer substrate by contact with a reducing solution, i.e. oranes, comprising copper ions, silver ions, or ions of lantanides, as proposed in referenced pending application Ser. No. 10/307,510. Alternatively, one can use compositions of metal hydrides described and used in conjunction with hydrogen fuel cells.

2. The wafer substrate is next contacted with formaldehyde type, or hypophosphite type electroless composition to achieve desired thickness of metal.

3. Using computer control, the wafer substrate is selectively irradiated, in order to define the desired pattern or image, after step #1 above, or after step #2., above. The latter option is at times preferred, and can be embodied via powerful laser, that will remove/burn thin (several angstrom thick) metal layer, i.e. copper, off the wafer surface. Once an image is delineated, additional copper thickness is obtainable by further contacted the thus patterned wafer with electroless solution.

When the substrate is selectively irradiated following step 1 above, the patterned wafer surface is contacted with electroless solution until the desired thickness is achieved.

4. In pursuing “pinpointed metalization”, for the purpose of repairing copper defects, the wafer is supplied selectively with electroless composition, at the pinpointed spot, or the electroless solution can be delivered to the entire wafer substrate, followed by pinpointed irradiation, i.e. laser, of the spot to be repaired, said irradiation serving to trigger copper deposition precisely and exclusively at the desired spot that is to be repaired.

1. A method of electrolessly depositing a metal on at least a part of the surface of a silicon wafer substrate, comprising:
(a) contacting the silicon wafer substrate with a solution comprising non-precious metal ions so as to obtain a wafer substrate covered with non-precious metal ions; and
(b) exposing the wafer substrate obtained in step (a) to a reducing solution comprising a reducing agent for reducing the metal ions that cover said substrate to a lower oxidation state.

2. The method according to claim 1, further comprising the step of:
(c) contacting the wafer substrate obtained in step (b) with an electroless copper plating solution.

3. The method according to claim 1, wherein at least one of steps (a) and (b) is carried out by puddle processing.

4. The method according to claim 2, wherein at least one of steps (a), (b) and (c) is carried out by puddle processing.

5. The method according to claim 1, wherein said reducing agent used in step (b) comprises a borane reducing agent.

6. The method according to claim 1, wherein said reducing solution used in step (b) comprises at least one metal ion of group Ib of the periodic table.

7. The method according to claim 2, wherein said deposited metal is copper.

8. The method according to claim 1, wherein the wafer substrate is scanned with a laser following step (b).

9. The method according to claim 2 further comprising during or after step (b), selectively scanning the wafer substrate with laser radiation in a predetermined manner.

10. The method according to claim 2 further comprising during or after step (c), selectively scanning the wafer substrate with laser radiation in a predetermined manner.

11. A method for forming a copper pattern on a silicon wafer substrate comprising (a) contacting the silicon wafer substrate with a solution comprising non-precious metal ions so as to obtain a wafer substrate covered with non-precious metal ions; (b) exposing the wafer substrate obtained in step (a) to a reducing solution comprising a reducing agent for reducing the metal ions that cover said substrate to a lower oxidation state; and (c) contacting the wafer substrate obtained in step (b) with an electroless copper plating solution.

12. The method according to claim 11, further comprising during or after step (b), selectively scanning the wafer substrate with laser radiation in a predetermined manner.

13. The method according to claim 11, further comprising during or after step (c), selectively scanning the wafer substrate with laser radiation in a predetermined manner.

14. A product of manufacture obtained by the method of claim 2.

15. A product of manufacture obtained by the method of claim 11.

16. A method of repairing dishing defects of copper on a ULSI device, comprising contacting at least said defected area of said device with electroless copper solution.

17. The method according to claim 16, wherein the electroless copper solution comprises formaldehyde reducer.

18. The method of claim 16, wherein the electroless copper solution comprises hypophosphite reducer.

19. The method according to claim 16, further comprising delivering radiation energy to at least said defected area, before, during, or after it is contacted with electroless copper.

20. The method according to claim 19, wherein the electroless copper solution comprises hypophosphite reducer.

21. The method according to claim 16, further comprising before contacting at least said defected area of said device with electroless copper solution, the following steps: contacting at least said defected area with a solution comprising non-precious metal ions; and than exposing said defected area to a reducing solution comprising a reducing agent.
